(19) United States
(12) Patent Application Publication
(10) Pub. No.: US 2025/0066902 A1
(43) Pub. Date: Feb. 27, 2025

(54) TEMPERATURE CONTROL SYSTEM, VACUUM SYSTEM, AND METHOD OF ADJUSTING THE TEMPERATURE OF A VACUUM CHAMBER OF A VACUUM SYSTEM

(71) Applicant: MAX-PLANCK-GESELLSCHAFT ZUR FÖRDERUNG DER WISSENSCHAFTEN E.V., München (DE)

(72) Inventors: Johannes BOSCHKER, Stuttgart (DE); Wolfgang BRAUN, Bietigheim-Bissingen (DE)

(21) Appl. No.: 18/729,559

(22) PCT Filed: Jan. 20, 2022
(86) PCT No.: PCT/EP2022/051196

§ 371 Date: Jul. 17, 2024

(51) Int. Cl. C23C 14/54; C23C 14/28

(52) U.S. Cl. CPC C23C 14/54; C23C 14/28

(57) ABSTRACT

The present invention relates to a temperature control system (10) for adjusting a temperature (60) of a vacuum chamber (102), the temperature control system (10) comprising conduits (20) which can be thermally coupled to a chamber wall (110) of the vacuum chamber (102), a fluid pump (50), temperature adjusting means (30) comprising a heating means (32) or both a heating means (32) and a cooling means (34), and tubing (52) for fluidly connecting said conduits (20), fluid pump (50), and temperature adjusting means (30), respectively. Further, the present invention relates to a vacuum system (100) with a vacuum chamber (102), the vacuum chamber (102) comprising a chamber wall (110) enclosing a vacuum volume (106), a vacuum pump system (104) connected to the vacuum chamber (102) for evacuating the vacuum volume (106), and a temperature control system (10) for adjusting a temperature (60) of a vacuum chamber (102). In addition, the present invention relates to a method of adjusting the temperature (60) of a vacuum chamber (102) of said vacuum system (100).

The invention relates to a temperature control system for adjusting a temperature of a vacuum chamber, the system comprising conduits which can be thermally coupled to a chamber wall of the vacuum chamber, a fluid pump, temperature adjusting means comprising a heating means or both a heating means and a cooling means, and tubing for fluidly connecting said conduits, fluid pump, and temperature adjusting means, respectively. Further, the invention relates to a vacuum system with a vacuum chamber, the vacuum chamber comprising a chamber wall enclosing a vacuum volume, a vacuum pump system connected to the vacuum chamber for evacuating the vacuum volume, and a temperature control system for adjusting a temperature of a vacuum chamber. In addition, the invention relates to a method of adjusting the temperature of a vacuum chamber of said vacuum system.

Vacuum systems comprising vacuum chambers, and hence a vacuum volume enclosed by a chamber wall of the vacuum chamber, are commonly used in modern technology. The vacuum volume chamber is sealable against ambient atmosphere and fillable with a reaction atmosphere. Said reaction atmosphere can be vacuum, in particular as low as 10⁻¹² hPa or even lower, or comprise reaction gases suitable for the respective application at pressures up to ambient pressure or even higher. An example for an application of said vacuum systems is thermal laser evaporation (TLE) for evaporating and/or sublimating material in a controlled environment provided in the vacuum chamber by means of laser heating, usually with the intent to coat a surface with a thin film.

Many applications of said vacuum chambers require a controlled adjustment of the temperature of the vacuum chamber and the enclosed vacuum volume, respectively. Some of the applications need cooling the vacuum chamber below ambient temperature, in particular even below 0° C. or even lower. On the other hand, also heating the vacuum chamber can be of advantage for some of the applications.

For instance, for reaching an ultrahigh vacuum in the vacuum chamber, a bake out procedure is performed for heating the vacuum chamber to temperatures of 100° C.-150° C. or higher so that gas species such as water vapor that are absorbed on the chamber wall of the vacuum chamber are desorbed and can be pumped out of the vacuum volume.

In present vacuum systems, dedicated means for cooling and heating of vacuum chambers are known. However, in particular heating systems for aforementioned bake out procedure, elaborate external heating systems are used, which need to be assembled for the bake out procedure and again disassembled afterwards. In addition, typically a large part of the exterior equipment on the vacuum chamber needs to be removed or must be specifically cooled because it cannot withstand the high temperatures involved. Because of this in particular said bake out procedures are time and cost consuming.

In view of the above, it is an object of the present invention to provide an improved temperature control system, an improved vacuum system, and an improved method of adjusting the temperature of a vacuum chamber of a vacuum system which do not have the aforementioned drawbacks of the state of the art. In particular, it is an object of the present invention to provide an improved temperature control system, an improved vacuum system, and an improved method which allow both cooling and heating of the vacuum chamber in an easy, cost and time efficient way, in particular without need of assembling and/or disassembling parts of the temperature control system or the vacuum system.

This object is satisfied by the respective independent patent claims. In particular, this object is satisfied by a temperature control system according to independent claim 1, by a vacuum system according to claim 9, and by method of adjusting the temperature of said vacuum chamber of a vacuum system according to claim 23. The dependent claims describe preferred embodiments of the invention. Details and advantages described with respect to a temperature control system according to the first aspect of the invention also refer to a vacuum system according to the second aspect of the invention and/or to a method according to the third aspect of the present invention, and vice versa, if of technical sense.

According to the first aspect of the invention, the object is satisfied by a temperature control system for adjusting a temperature of a vacuum chamber, the system comprising conduits which can be thermally coupled to a chamber wall of the vacuum chamber, a fluid pump, temperature adjusting means comprising a heating means or both a heating means and a cooling means, and tubing for fluidly connecting said conduits, fluid pump, and temperature adjusting means, respectively, wherein the fluid pump is capable of pumping a heating fluid heated by the heating means through the conduits for heating the vacuum chamber, or of pumping both a heating fluid heated by the heating means and a cooling fluid cooled by the cooling means through the conduits for both heating and cooling the vacuum chamber, respectively.

The temperature control system according to first aspect of the present invention is intended for usage with a vacuum system, in particular with a vacuum chamber of said vacuum system. The temperature control system comprises temperature adjusting means comprising heating means or both heating means and cooling means. Preferably, the temperature adjusting means comprises means for both heating a heating fluid and cooling a cooling fluid, respectively. In other words, with a temperature control system according to first aspect of the present invention heating of the vacuum chamber can easily be provided. In particular, no additional external heater is necessary for heating the vacuum chamber. Preferably, both cooling and heating, respectively, of the vacuum chamber can be provided by the temperature control system according to the present invention, in particular by a single device. Time-consuming and costly assembly and disassembly of separate devices for cooling and heating, respectively, of the vacuum chamber can thus be avoided.

The heated heating fluid, and if applicable also the cooled cooling fluid, respectively, are conveyed and pumped within the temperature control system by a fluid pump. In the scope of the present invention, the cooling fluid and the heating fluid, respectively, can be both gaseous or liquid, respectively.

Preferably, the fluid pump can be provided as single pump for pumping both fluids. Alternatively, also two separate pump devices can be used and combined with respective switches to the fluid pump according to the present invention, in particular if the temperature difference between the cooled cooling fluid and the heated heating fluid is too great to be sustained by a single pumping device.

Further, the tubing comprised by the temperature control center according to the present invention provides a fluidly connection of the different elements of the temperature control system. Said tubing can be provided as flexible hoses and/or rigid pipes. Also switches, reservoirs, expansion tanks and similar fluidic components are considered as tubing in the scope of the present invention.

A further element of the temperature control system according to the invention are the conduits which can be thermally coupled to a chamber wall of the vacuum chamber. The conduits are fluidly connected to the other components of the temperature control system, in particular the means for cooling and heating, and the fluid pump, by the aforementioned tubing. Hence, cooled cooling fluid and heated heating fluid can be pumped through the conduits. In particular, the conduits can be used for both fluids, the cooling fluid and the heating fluid, respectively. By the thermal coupling of the conduits to the chamber wall a direct cooling and heating, respectively, of the chamber wall and thereby of the vacuum chamber can be provided.

During usage of the temperature control system according to first aspect of the present invention, the conduits during are thermally coupled directly to the chamber wall of the vacuum chamber. Hence a cooling and heating effect, respectively, is directly generated in the chamber wall of the vacuum chamber. In particular, said effects are locally limited and positions of an application of the cooling and heating provided by the temperature control system according to first aspect of the present invention can easily be selected by an accordingly selected arrangement of the conduits. Exterior equipment on the vacuum chamber, which cannot withstand the low and/or high temperatures involved, can therefore easily be spared and extensively recessed by a respective arrangement of the conduits at and/or in the chamber wall of the vacuum chamber.

In summary, a temperature control system according to the first aspect of the present invention provides heating, preferably both heating and cooling, of the vacuum chamber in an easy, cost and time efficient way. In particular, as the same conduits are used for a flow of the cooling fluid and heating fluid, respectively, and hence for both cooling and heating, respectively, assembling and disassembling of parts of the temperature control system or the vacuum system for a change between cooling and heating can be avoided.

Further, the temperature control system according to first aspect of the present invention can be characterized in that the temperature adjusting means comprises both the heating means and the cooling means, whereby the heating means and the cooling means are integrated in a combined temperature adjusting device. In this embodiment, a single temperature adjusting means provides both, cooling and heating, respectively. The temperature control system in this embodiment can thereby be provided more compact and/or with a reduced complexity.

In addition, the temperature control system according to first aspect of the present invention can comprise that the cooling fluid and the heating fluid are different fluids. By using dedicated and different fluids as cooling fluid and heating fluid, respectively, both processes, namely cooling and heating of the vacuum chamber, can be carried out with a fluid most suitable for the respective process. An efficiency of said cooling and heating processes can thereby be enhanced. Additionally, also the temperatures of the vacuum chamber providable by the temperature control system according to first aspect of the present invention, namely a lowest temperature reachable by cooling the vacuum chamber and a highest temperature reachable by heating the vacuum chamber, can thereby be taken to their respective extreme.

Alternatively, the temperature control system according to first aspect of the present invention can be characterized in that a common temperature adjusting fluid is used as both the cooling fluid and the heating fluid, respectively. In the embodiment described in the previous paragraph, switching between cooling and heating, and vice versa, demands a change of the fluid present in the active elements of the temperature control system such as in particular the conduits. By using a common temperature adjusting fluid for both processes, namely cooling and heating of the vacuum chamber, this drawback can be avoided. In particular, switching between cooling and heating is possible without any need for a change of the fluid present in the conduits. An especially fast execution of cooling and heating of the vacuum chamber can thereby be provided. Preferably, the temperature adjusting fluid is selected such that the expected range of temperature adjustments during the use of the vacuum system comprising the vacuum chamber can be covered. Further, the temperature control system according to first aspect of the present invention can comprise that the heating means is capable of heating the heating fluid to a temperature of 100° C. or higher, preferably of 150° C. or higher. Such high temperatures are needed in some applications of vacuum systems. Especially, said temperatures are suitable for so called bake out procedures. By heating the vacuum chamber during the bake out procedures to temperatures of 100° C. or higher, preferably of 150° C. or higher, a removal of gas species such as water vapor that are absorbed on the inner chamber walls of the vacuum chamber can be provided. Hence, such bake out procedures are a key ingredient towards achieving low pressures, in particular an ultrahigh vacuum (UHV).

Additionally, or alternatively, the temperature control system according to first aspect of the present invention can be characterized in that the cooling means is capable of cooling the cooling fluid to a temperature of 0° C. or lower, in particular of −196° C. or lower. Such low temperatures are needed in some applications of vacuum systems. Especially, also said temperatures, in particular the temperature of liquid nitrogen at −196° C., are suitable for maintaining low pressures, in particular an ultrahigh vacuum (UHV), as gas species still absorbed in the inner chamber walls are kept frozen and a desorption of these gases can be efficiently suppressed.

Preferably, the temperature control system according to first aspect of the present invention further comprises that the temperature control system comprises one or more sensors for measuring the temperature of the vacuum chamber and/or for measuring the temperature of the heating fluid and/or the cooling fluid, respectively. By providing one or more sensors the actual temperature of the vacuum chamber and/or the heating fluid and/or the cooling fluid can be monitored. A demand for cooling or heating can thereby be detected both very easily by evaluating said measured temperature and also promptly.

According to another embodiment of the temperature control system according to first aspect of the present invention, the tubing is provided as detachable tubing for allowing a separation of the fluid pump, and the temperature adjusting means, respectively, from the conduits. In some applications of vacuum systems, controlling the temperature of the vacuum chamber is only needed for a limited time, for example only for a bake out procedure as described above. In this situation, it can be of advantage to detach the fluid pump, and the temperature adjusting means, respectively, from the conduits. Again, the temperature adjusting means can comprise heating means or preferably both, heating means and cooling means, respectively. The conduits stay arranged and thermally connected to the vacuum chamber, but the residual elements of the temperature control system can be dismantled and preferably stockpiled for later reuse. A disturbance of the application of the vacuum chamber by actually not needed elements of the temperature control system can thereby be avoided.

According to a second aspect the object of the present invention is satisfied by a vacuum system with a vacuum chamber, the vacuum chamber comprising a chamber wall enclosing a vacuum volume, a vacuum pump system connected to the vacuum chamber for evacuating the vacuum volume, and a temperature control system for adjusting a temperature of a vacuum chamber. A vacuum system according to the second aspect of the present invention is characterized in that the temperature control system is constructed according to one of the preceding claims and the conduits of the temperature control system are thermally coupled to the chamber wall.

The vacuum systems according to the second aspect of the present invention comprises a vacuum chamber with a vacuum volume enclosed by a chamber wall of the vacuum chamber. The vacuum volume chamber is sealable against ambient atmosphere and fillable with a reaction atmosphere. Said reaction atmosphere can be vacuum, in particular as low as 10⁻¹² hPa or even lower, or comprise reaction gases suitable for the respective application at pressures up to ambient pressure or even higher. An example for an application of said vacuum systems is thermal laser evaporation (TLE) for evaporating and/or sublimating material in a controlled environment provided in the vacuum chamber by means of laser heating, usually with the intent to coat a surface with a thin film.

As many applications of said vacuum chamber according to the second aspect of the present invention require a controlled adjustment of the temperature of the vacuum chamber and the enclosed vacuum volume, respectively, the vacuum system according to the second aspect of the present invention comprises a temperature control system according to the first aspect of the present invention. By that, the vacuum system according to the second aspect of the present invention provides all features and advantages described above with respect to the temperature control system according to the first aspect of the present invention.

The conduits of the temperature control system are thermally coupled to the chamber wall. In other words, cooling and heating, respectively, of the chamber wall and hence of the vacuum chamber can be reliably provided. By changing the temperature of the cooling fluid or heating fluid flowing in the conduits, the temperature of the vacuum chamber can be influenced and altered directly. For the thermal coupling, the conduits can be temporarily or permanently attached to the chamber wall of the vacuum chamber.

According to an embodiment of the vacuum system according to second aspect of the present invention, the conduits are at least partly integrated into the chamber wall. Integrated in the scope of the present invention in particular encompasses that the respective part of the conduits is directly formed by the chamber walls. Thermally coupling the conduits to the chamber wall can thereby be provided and ensured especially easily.

The vacuum system according to second aspect of the present invention can be enhanced further by that the chamber wall is at least partly constructed as a double-walled structure, whereby an interstitial space of the double-walled structure forms at least part of the conduits. The interstitial space can be formed as pipes and/or extensive cavities. In particular, in this embodiment of the vacuum system according to second aspect of the present invention large parts of the vacuum chamber can be cooled or heated, respectively, especially easily.

Additionally, or alternatively, the vacuum system according to second aspect of the present invention can comprise that the chamber wall comprises one or more internal ducts in the bulk of the chamber wall, wherein the one or more internal ducts form at least part of the conduits. For this embodiment, the chamber wall of the vacuum chamber is at least partly provided as a single-wall structure. In this single chamber wall, an internal duct is provided, either already during the production of the chamber wall or as subsequently inserted opening. By providing an internal duct in the chamber wall, again the thermal coupling between the respective conduits, and hence the cooling fluid and/or heating fluid flowing in the conduits, and the chamber wall can be ensured especially easily.

Preferably, the vacuum system according to second aspect of the present invention can be enhanced by that the one or more internal ducts are provided as pairs of straight and V-shaped arranged bores. Each duct comprises two straight bores which start at the outer surface of the chamber wall at separate locations and meet within the bulk of the chamber wall. Thereby, the V-shape of the internal duct is formed. Arranging said bores is an easy and standard machining step. By selecting the diameter of the respective bores and/or the depth within the bulk of the chamber wall of their meeting point, a cooling and heating, respectively, capacity of the temperature control system can be adjusted.

In another embodiment of the vacuum system according to second aspect of the present invention, the conduits are at least partly attached to the outside of the chamber wall. Also, this external attachment leads to an effective thermal coupling of the conduits to the chamber wall. Attaching at least a part of the conduits on an outside surface of the chamber wall of the vacuum chamber provides the possibility of post-installation of said respective conduits. In particular, also already existing vacuum systems can be upgraded to vacuum systems according to the present invention by attaching conduits on the outer surface of the vacuum chamber and providing the other elements of the temperature control system according to the first aspect of the present invention.

In particular, the vacuum system according to second aspect of the present invention can be enhanced by that the conduits are at least partly provided as tubes, wherein the tubes attached and thermally coupled to the outside of the chamber wall. Tubes are a common form of elements for providing and guiding a flow of fluid. By thermally attaching said tubes to an outer surface of the vacuum chamber, the advantages of a common system for directing a flow of a fluid and the direct cooling and heating ability of the temperature control system according to the first aspect of the present invention with respect to the vacuum chamber can be combined.

In another enhancement of the vacuum system according to second aspect of the present invention, the tubes are soldered and/or welded to the outside of the chamber wall. Soldering and/or welding, respectively, is a substance-to-substance connection between the tubes forming the conduits on the one hand and the surface of the vacuum chamber on the other hand. Hence, by soldering and/or welding the tubes are firmly and inseparably attached to the outside of the vacuum chamber. Additionally, said types of substance-to-substance connections can be provided such that there is a direct physical contact between the respective tube and the chamber wall. The thermal coupling between the conduit formed by the tube and the vacuum chamber can thereby be enhanced further.

Further, the vacuum system according to second aspect of the present invention can comprise that the tubes consists of a material with a thermal conductivity higher than 200 W/mK, in particular of Copper and/or Aluminum. Within the tubes, the cooling fluid and/or the heating fluid flows during an operation of the temperature control system according to the first aspect of the present invention. By using a material with a thermal conductivity higher than 200 W/mK, an exchange of thermal energy, from the chamber wall into the cooling fluid in the case of cooling the vacuum chamber and vice versa in the case of heating the vacuum chamber, can proceed undisturbed or at least essentially undisturbed. Both Copper and Aluminum are suitable materials for the manufacture of tubes providing this property.

Alternatively, or additionally, the vacuum system according to second aspect of the present invention can be characterized in that elongated concave structural elements are attached to the chamber wall, whereby an interstitial space between the chamber wall and the respective structural element forms at least part of the conduits. Compared to the embodiment described in the paragraph above, in this embodiment the outside surface of the chamber wall of the vacuum chamber itself forms a part of the conduits. The elongated concave structural elements are attached to the chamber wall and the contact surfaces between the structural elements and the chamber wall are sealed. Hence, the structural elements and the respective part of the chamber wall enclose an interstitial space in which the cooling fluid and/or the heating fluid can flow. As the inner boundary of this interstitial space is formed by the chamber wall itself, a thermal coupling to the vacuum chamber is automatically provided, in particular with its highest possible design.

In addition, the vacuum system according to second aspect of the present invention can comprise that the structural elements are soldered and/or welded to the outside of the chamber wall. Again, soldering and/or welding, respectively, is a substance-to-substance connection between the structural elements and the chamber wall of the vacuum chamber. Hence, by soldering and/or welding the structural elements are firmly and inseparably attached to the outside of the vacuum chamber.

According to another embodiment of the vacuum chamber according to the present invention, the conduits are arranged such at the chamber wall that the temperature control system is capable of cooling and heating, respectively, of more than 25%, preferably more than 50%, most preferably of more than 75%, of the chamber wall. By attaching and thermally coupling the conduits of the temperature control system according to the first aspect of the present invention directly to the chamber wall of the vacuum chamber of the vacuum system according to the second aspect of the present invention, a direct cooling and heating of the vacuum chamber can be provided. By a capability of cooling and heating of more than 25%, preferably more than 50%, most preferably of more than 75%, of the chamber wall, a temperature adjustment of the whole vacuum chamber can be provided. In particular, said capability is accompanied by a respective coverage of the outer surface of the vacuum chamber with conduits of the temperature control system according to the first aspect of the present invention.

Further, the vacuum system according to second aspect of the present invention can comprise that conduits are at least essentially evenly or evenly distributed over the chamber wall. By providing an at least essentially even or even distribution of the conduits over the chamber wall, also an at least essentially even or even cooling and heating of the vacuum chamber as a whole can be provided. Sections of the vacuum chamber insufficiently cooled or heated by the temperature control system according to first aspect of the present invention can be avoided.

In addition, the vacuum system can be characterized in that the vacuum system comprises one or more sensors for measuring the temperature of the vacuum chamber and/or for measuring the temperature of the heating fluid and/or the cooling fluid, respectively. By measuring the temperature of the vacuum chamber itself, a direct control of said temperature of the vacuum chamber is possible. If the measured temperature is too high, a reduction of heating or an increase of cooling the vacuum chamber can be initialized. Vice versa, if the measured temperature is too low, an increase of heating or a reduction of cooling the vacuum chamber can be necessary. By measuring the temperature of the heating fluid and/or the cooling fluid, respectively, an indirect measure of said temperature of the vacuum chamber can be provided. If the temperature of the respective fluid is lower after flowing through the conduits, thermal energy is transferred to the vacuum chamber resulting in a heating of the vacuum chamber, if the temperature of the respective fluid is higher after flowing through the conduits, thermal energy is transferred from the vacuum chamber into the fluid resulting in a cooling of the vacuum chamber. In both cases, if the temperature of the fluid stays at least essentially constant before and after flowing through the conduits, the temperature of the vacuum chamber should be essentially equal to the temperature of the fluid. Preferably, the output of the sensor can be used for a closed loop control of the cooling and heating of the vacuum chamber provided by the temperature control system according to the first aspect of the present invention.

According to a third aspect of the invention, the object can be satisfied by a method of adjusting the temperature of a vacuum chamber of a vacuum system according to the second aspect of the present invention, comprising the steps of
a) measuring the temperature of the vacuum chamber;
b) evaluating the temperature measured in step a) at least by comparing the temperature with an upper limit value and/or a lower limit value; and
c) cooling or heating, respectively, of the vacuum chamber by the temperature control system, if the temperature evaluated in step b) exceeds the upper limit value or falls short of the lower limit value.

The method according to the third aspect of the present invention can be carried out with and/or by a vacuum system according to the second aspect of the present invention. In particular, said vacuum system according to the second aspect of the present invention comprises a temperature control system according to the first aspect of the present invention. By that, the method according to the third aspect of the present invention provides all features and advantages described above with respect to the temperature control system according to the first aspect of the present invention and additionally with respect to the vacuum system according to the second aspect of the present invention.

In the first step a) of the method according to the third aspect of the present invention, the temperature of the vacuum chamber is measured. This can preferably be provided by an accordingly selected sensor of the temperature control system according to the first aspect of the present invention and/or of the vacuum system according to the second aspect of the present invention. In summary, after execution of step a) an information about the actual and present temperature of the vacuum chamber is available.

Further, in the next step b) of the method according to the third aspect of the present invention, the temperature measured in step a) is evaluated. In particular, said temperature is at least compared with an upper limit value and/or a lower limit value. Said limit values are preferably selected according to the needs of the vacuum system, for instance with respect to the current application of the vacuum system.

Finally, in step c) of the method according to the third aspect of the present invention, based on the evaluation of the temperature carried out in step b), cooling or heating, respectively, of the vacuum chamber by the temperature control system according to the first aspect of the present invention is performed. In particular, if the temperature evaluated in step b) exceeds the upper limit value, the temperature of the vacuum chamber is too high and cooling of the vacuum chamber is initiated. On the other hand, if the temperature evaluated in step b) falls short of the lower limit value, the temperature of the vacuum chamber is too low and heating of the vacuum chamber is started.

In step c) of the method according to the third aspect of the present invention, heating and cooling, respectively, can easily be provided with a temperature adjusting means comprising both heating means and cooling means, respectively. However, also for an embodiment in which the temperature adjusting means only comprises a heating means, if the temperature evaluated in step b) exceeds the upper limit value, switching off the heating means effectively results in cooling the vacuum chamber. If the temperature evaluated in step b) falls short of the lower limit value heating the vacuum chamber can be provided straight forward by heating the heating fluid by the heating means.

In summary, the method according to the third aspect of the present invention provides an active control of the temperature of a vacuum chamber. Operating the vacuum system with the respective vacuum chamber at a required temperature can thereby be provided.

Further, the method according to the third aspect of the present invention can be characterized in that in step a) the temperature of the vacuum chamber is measured directly and/or the temperature of the vacuum chamber is measured indirectly by measuring the temperature of the heating fluid and/or the cooling fluid, respectively. A direct measurement of the temperature of the vacuum chamber can be provided for instance by attaching and/or integrating respective sensors directly to the chamber wall of the vacuum chamber. In contrast to that, an indirect measurement of the temperature can be provided for instance by measuring the temperature of the cooling fluid or the heating fluid. For instance, the difference of an input and output temperature of the cooling fluid or the heating fluid, respectively, determines the direction and magnitude of the energy flow and hence whether the temperature of the vacuum chamber is higher or lower than the input temperature. By that, the input temperature can be used to at least approximately control the temperatures of the system. In both cases, a determination of the temperature of the vacuum chamber can be provided.

According to an embodiment of the method according to the third aspect of the present invention, in step b) the measured temperature is compared with both the upper limit value and the lower limit value. In other words, in step b) the measured temperature is tested whether it falls short of the lower limit value and additionally whether it exceeds the upper limit value. An even more detailed information about the actual temperature of the vacuum chamber can thereby be gained.

According to a first alternative enhancement of the method according to the third aspect of the present invention, the upper limit value is higher than the lower limit value. In this case, the upper limit value and the lower limit value limit a region of allowed values for the temperature of the vacuum chamber. Hence, operating the vacuum chamber within said temperature region can be provided.

In a second alternative enhancement of the method according to the third aspect of the present invention, the lower limit value is higher than the upper limit value. In contrast to the alternative described in the previous paragraph, now the upper limit value and the lower limit value limit a region of forbidden values for the temperature of the vacuum chamber. This can be of advantage for operations of the vacuum system for which an operation of the vacuum chamber within said temperature region has to be avoided, for instance for suppressing undesired chemical reactions in the vacuum chamber.

According to a preferred embodiment of the method according to the third aspect of the present invention, steps a) to c) are repeatedly carried out, preferably continuously carried out, for a closed loop control of the temperature of the vacuum chamber. A continuous control of the temperature of the vacuum chamber can thereby be provided. Said closed loop control can be for instance be carried out by a suitable computational element such as a control device and/or a computer.

In addition, the method according to the third aspect of the present invention can comprise that a heating of the vacuum chamber by the temperature control system can be used for a bake out procedure of the vacuum chamber. For this, heating the heating fluid to a temperature of 100° C. or higher, preferably of 150° C. or higher is advantageous. Such high temperatures are suitable for so called bake out procedures. By heating the vacuum chamber during the bake out procedures to temperatures of 100° C. or higher, preferably of 150° C. or higher, a removal of gas species such as water vapor that are absorbed on the inner chamber walls of the vacuum chamber can be provided. Hence, such bake out procedures are a key ingredient towards achieving low pressures, in particular an ultrahigh vacuum (UHV).

Further, the method according to the third aspect of the present invention can be characterized in that the temperature control system comprising a detachable tubing, and wherein before the first execution of step a) the detachable tubing is used connect the fluid pump, the temperature adjusting means, and the conduits, and/or wherein after the last completion of step c) the detachable tubing is used separate the fluid pump, the temperature adjusting means, and the conduits. In some applications of vacuum systems, controlling the temperature of the vacuum chamber is only needed for a limited time, for example only for a bake out procedure as described above. In this situation, it can be of advantage to detach the fluid pump, the temperature adjusting means from the conduits after completion of said task. On the other hand, if later on again controlling and/or adjusting the temperature of the vacuum chamber becomes necessary, the fluid pump, the temperature adjusting means can be reattached to the conduits. However, the conduits stay arranged and thermally connected to the vacuum chamber at all times, but the residual elements of the temperature control system can be dismantled and preferably stockpiled for later reuse. In particular, said detachment and reattachment also encompasses draining and filling the temperature control system with the respective fluids, namely the temperature adjusting fluid and/or the heating fluid and/or the cooling fluid. Again, the temperature means can comprise heating means or both, heating means and cooling means, respectively.

The invention will be explained in detail in the following by means of embodiments and with reference to the drawings in which are shown:

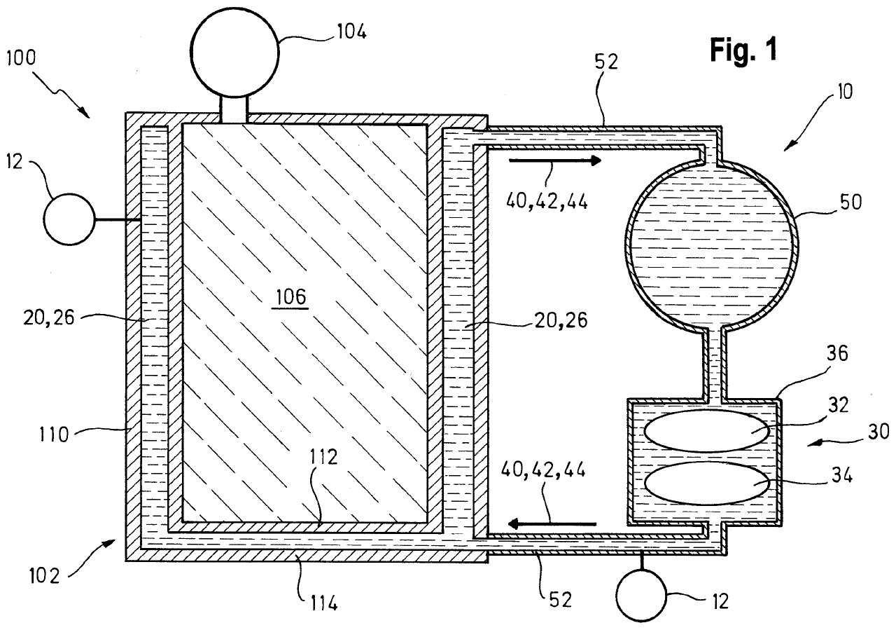

FIG. 1 Schematic view of a vacuum system according to the present invention,

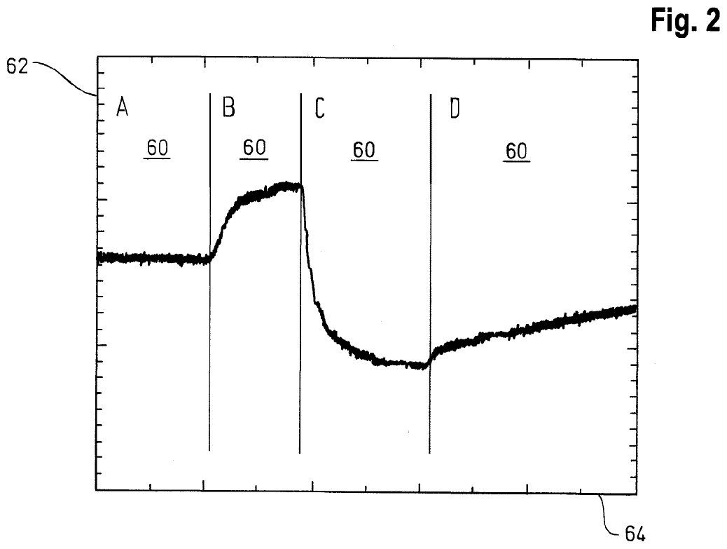

FIG. 2A measurement of temperature dependent pressure change in a vacuum chamber according to the present invention,

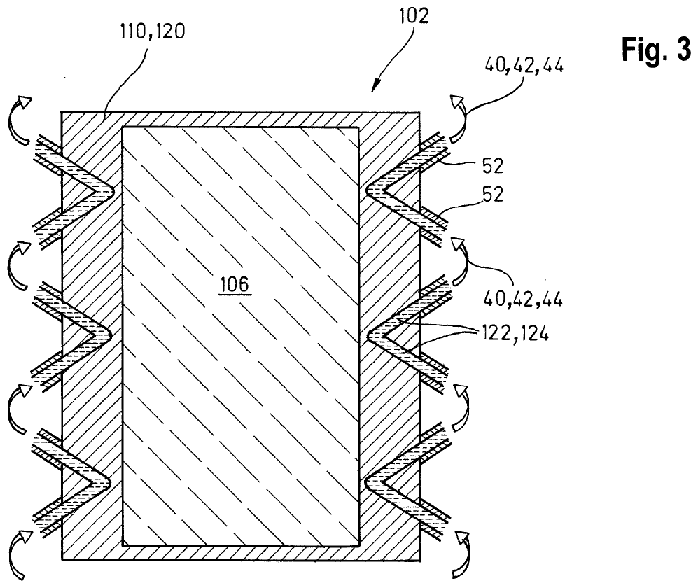

FIG. 3A first possible embodiment of conduits,

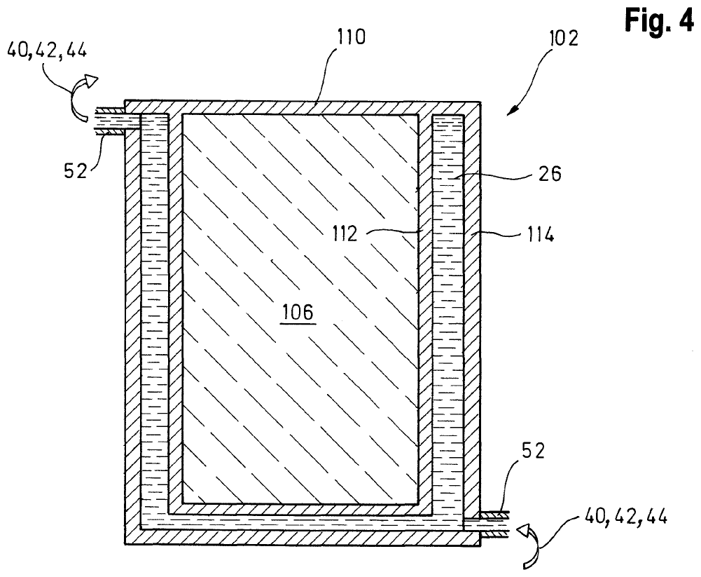

FIG. 4A second possible embodiment of conduits,

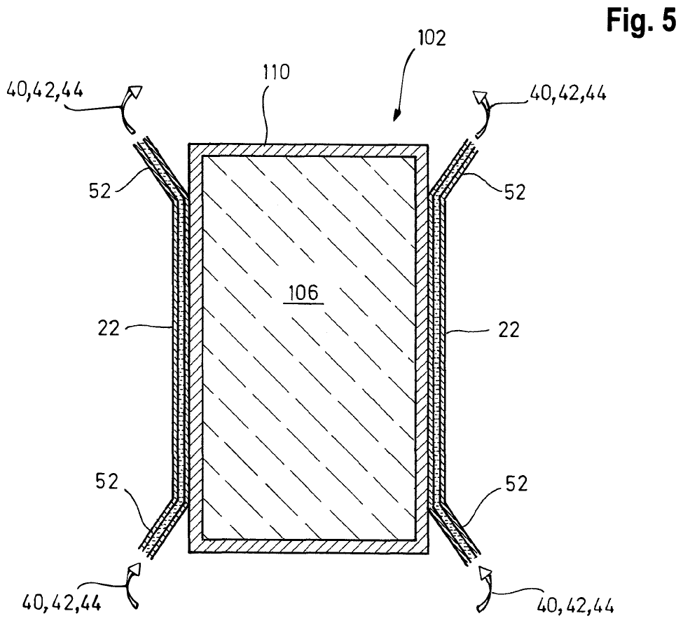

FIG. 5A third possible embodiment of conduits, and

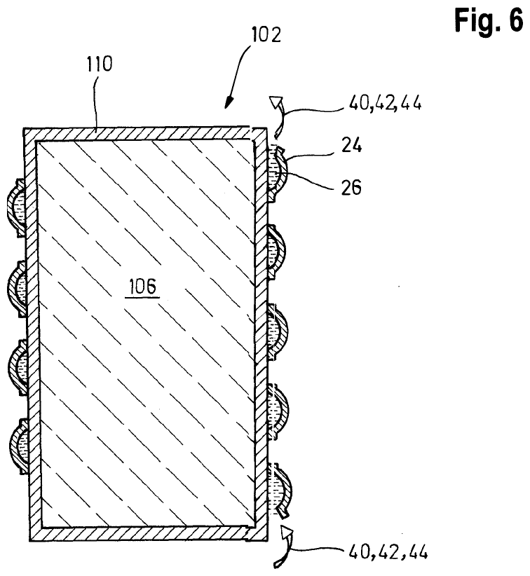

FIG. 6A fourth possible embodiment of conduits,

FIG. 1 shows a schematic view of a vacuum system 100 according to the present invention. The vacuum system 100 comprises a vacuum chamber 102 with a chamber wall 110 enclosing a vacuum volume 106. A vacuum pump system 104 of the vacuum system 100 provides a selectable reaction atmosphere within the vacuum volume 106, for instance a vacuum as low as 10−12 hPa or even lower, or a reaction atmosphere containing reaction gases suitable for an intended application of the vacuum system 100 at pressures up to ambient pressure or even higher.

In particular, the vacuum system 100 according to the present invention comprises a temperature control system 10 according to the present invention. In the depicted embodiment, said temperature control system 10 is capable of both cooling and heating of the vacuum chamber 102. For said purpose, the temperature control system 10 comprises heating means 32 and cooling means 34, which can, as depicted schematic view in FIG. 1, be integrated into a combined temperature adjusting device 36. In another and not shown embodiment, also a temperature adjusting means 30 comprising only heating means 32 is possible. A Fluid pump 50 is provided as part of the temperature control system 10 for pumping heating fluid 42 heated by the heating means 32 and cooling fluid 44 cooled by the cooling means 34, respectively. According to the present needs and boundary conditions of the specific vacuum system 100, whose temperature 60 is to be adjusted and/or controlled, said heating fluid 42 and cooling fluid 44 can be provided as different fluids or as a common temperature adjusting fluid 40.

Further, the temperature control system 10 comprises conduits 20, which can be thermally coupled to the chamber wall 110 of the vacuum chamber 102. As shown in FIG. 1, for the vacuum system 100 according to the present invention, the conduits 20 actually are thermally coupled to the chamber wall 110, in the depicted embodiment of the vacuum chamber 102 even integrated into the chamber wall 110 as interstitial space 26 between an inner wall 112 and an outer wall 114 of a chamber wall 110 comprising a double-walled structure. Other possible embodiments of the conduits 20 and their respective thermal coupling to the chamber wall 110 are shown in FIGS. 3 to 6.

In particular, the conduits 20 are arranged in such a way at the chamber wall 110 that they ensure sufficient coverage. Preferably, more than 25%, preferably more than 50%, most preferably of more than 75%, of the chamber wall 110 can be cooled and heated, respectively, by the respective fluid flowing through the conduits 20. For a most uniform temperature 60 control of the vacuum chamber 102, the conduits 20 can be at least essentially evenly or evenly distributed over the chamber wall 110.

The conduits 20 and also the remaining elements of the temperature control system 10 are fluidly connected by tubing 52. Said tubing can be detachable for removing the fluid pump 50 and the heating means 32 and cooling means 34, respectively, if actually no temperature control for the vacuum chamber 102 is needed. Consequently, if a need for temperature control is imminent, the fluid pump 50, the heating means 32 and cooling means 34, respectively, can be reattached to the conduits 20. In particular, said detachment and reattachment also encompasses draining and filling the temperature control system 10 with the respective fluids, namely the temperature adjusting fluid 40 and/or the heating fluid 42 and/or the cooling fluid 44.

Essentially for the present invention, the conduits 20, and hence the temperature control system 10 according to the present invention, are used at least for heating, preferably and as depicted in FIG. 1, for both, heating and cooling, respectively, of the vacuum chamber 102. With respect to the present needs of the vacuum system 100, heated heating fluid 32 or cooled cooling fluid 34 is pumped through the conduits 20 thereby adjusting the temperature 60 of the vacuum chamber 102. Preferably, temperatures 60 of the cooling fluid 44 of 0° C. or lower, in particular of −196° C. or lower and of the heating fluid 42 of 100° C. or higher, preferably of 150° C. or higher, respectively, can be provided by the cooling means 34 and the heating means 32, respectively. Via the thermal coupling of the conduits 20 to the chamber wall 110, these temperatures 60 can also be reached for the vacuum chamber 102. Such high temperatures 60 of the vacuum chamber 102 can especially be used for bake out procedures of the vacuum chamber 102.

Further, sensors 12 can be provided as element of the vacuum system 100 and/or of the temperature control system 10. These sensors 12 can be used for measuring the temperature 60 of the vacuum chamber 102. These temperature measurements can be provided directly by arranging the respective sensor at the chamber wall 110, or indirectly by measuring the temperature 60 of the cooling fluid 34 and the heating fluid 32, respectively. Preferably, said measured temperatures 60 can be used as input for a closed loop control of a temperature 60 adjustment of the vacuum chamber 102.

The aforementioned closed loop control is an enhancement of a general method of adjusting the temperature 60 of the vacuum chamber 102 providable by the vacuum system 100 and the temperature control system 10, respectively, according to the present invention. In a first step a), the temperature 60 of the vacuum chamber 102 is measured.

Said measured temperature 60 can then be evaluated in a following step b) by comparing it with an upper limit value or a lower limit value, preferably with both an upper limit value and a lower limit value. With respect to the boundary conditions and needs set by the vacuum system 100 and its intended application, upper limit value can be higher than the lower limit value and vice versa.

Based on the result of the evaluation executed in step b), in a final step c) adjusting the temperature 60 of the vacuum chamber 102 by the temperature control system is performed. In particular, if the temperature 60 exceeds the upper limit value heating of the vacuum chamber 102, if the temperature 60 falls short of the lower limit value heating of the vacuum chamber 102, respectively, is provided.

FIG. 2 depicts the general dependency of a pressure 62 inside a vacuum chamber 102 (see FIG. 1) on a temperature 60 of the vacuum chamber 102. The horizontal axis represents time 64 and the vertical axis the pressure 62 inside the vacuum chamber 102. In the first time 64 section, denoted with “A”, the temperature 60 is constant and hence also the pressure 60 shows no change.

In the next time 64 slice “B”, the temperature 60 of the was increased by the temperature control system 10 (see FIG. 1). Gas species such as water vapor absorbed on the chamber wall 110 are desorbed more and hence the pressure 62 within the vacuum volume 106 also increases. By additional pumping provided by the vacuum pump system 104, also these desorbed gases can be removed from the vacuum volume 106 and hence after switching of the heating an even lower resulting pressure 62 in the vacuum chamber 102 can be reached. This is the principle of the so called bake out procedures.

Next, in the following time 64 section “C”, the temperature 60 was again lowered, in particular below its respective value in time 64 slice “A”. In this case, the desorption of the gases mentioned above is reduced, also resulting in a pressure 62 in the vacuum chamber 102 lower than at the beginning of the procedure depicted in section “A”. Gas species still absorbed in the inner chamber walls are kept frozen and a desorption of these gases can be efficiently suppressed.

All these processes described with respect to time sections “B” and “C”, respectively, are reversible. This is shown in time slice “D”, in which the temperature 60 was again set to its value of time 64 slice “A”. The pressure 62 returns also to its initial value, even if slowly. In particular, pressures 62 even lower than the initial pressure 62 of time slice “A” are possible for high temperatures 60 beyond 100° C.-150° C. due to bake out effects.

In FIGS. 3 to 6, different possibilities of embodiments of conduits 20 and their respective thermal connection to the chamber wall 110 are depicted. FIG. 3, 4 show embodiments in which the conduits 20 are integrated into the chamber walls 110, FIG. 5, 6 show embodiments in which the conduits 20 are externally attached to the chamber walls 110. In all figures, only the vacuum chamber 110 and the conduits 20 are shown. Nevertheless, it goes without saying that also FIGS. 3 to 6 represent the vacuum system 100 and the temperature control system 10, respectively, according to the present invention.

FIG. 3 shows an embodiment of the vacuum chamber 102 with a plurality of internal ducts 122 are arranged in the bulk 120 of the chamber wall 110. The internal ducts 122 are provided as pairs of straight and V-shaped arranged bores 124. The straight bores 124 start at the outer surface of the chamber wall 110 at separate locations and meet within the bulk 120 of the chamber wall 110. In particular, these internal ducts 122 are used as conduits 20 for the temperature control system 10 according to the present invention. By providing these internal ducts 122 in the chamber wall 110, the thermal coupling between the respective conduits 20, and hence the cooling fluid 44 and/or heating fluid 42 flowing in these conduits 20, and the chamber wall 110 can be ensured especially easily. In addition, by selecting the diameter of the respective bores 124 and/or the depth within the bulk 120 of the chamber wall 110 of their meeting point, a cooling and heating, respectively, capacity of the temperature control system 10 can be adjusted.

As depicted in FIG. 4, alternatively, or additionally, the chamber wall 110 can also be at least partly constructed as a double-walled structure, whereby an interstitial space 26 between an inner wall 112 and an outer wall 114 of the chamber wall 110 forms at least part of the conduits 20. The interstitial space 26 can be formed for instance as internal pipes and/or extensive cavities. As thereby the conduits 20 are arrangeable directly in a large fraction of the chamber wall 110, large parts of the vacuum chamber 110 can be cooled or heated, respectively, especially easily.

In the embodiment depicted in FIG. 5, tubes 22 are attached, preferably soldered and/or welded, and thermally coupled to the outer surface of the chamber wall 110 and form the conduits 20. In particular, materials with a thermal conductivity higher than 200 W/mK, in particular of Copper and/or Aluminum, can be used for said tubes 22.

As depicted in FIG. 6, also elongated concave structural elements 24 attached, preferably soldered and/or welded, to the chamber wall 110 can be used to provide the conduits, whereby an interstitial space 26 between the chamber wall 110 and the respective structural element 24 forms the actual conduit 20. The contact surfaces between the structural elements 24 and the chamber wall 110 are sealed. In this embodiment, the outside surface of the chamber wall 110 itself forms a part of the conduits 20. Hence, a thermal coupling of a cooling fluid 44 or a heating fluid 42, respectively, flowing in the formed interstitial space 26 to the vacuum chamber 102 is automatically provided, in particular with its highest possible design.

### LIST OF REFERENCES

10 temperature control system
12 sensor
20 conduits
22 tube
24 structural element
26 interstitial space
30 temperature adjusting means
32 heating means
34 cooling means
36 temperature adjusting device
40 temperature adjusting fluid
42 heating fluid
44 cooling fluid
50 fluid pump
52 tubing
60 temperature
62 pressure
64 time
100 vacuum system
102 vacuum chamber
104 vacuum pump system
106 vacuum volume
110 chamber wall
112 inner wall
114 outer wall
120 bulk
122 duct
124 bore

1-30. (canceled)

31. Temperature control system for adjusting a temperature of a vacuum chamber, the temperature control system comprising conduits which can be thermally coupled to a chamber wall of the vacuum chamber, a fluid pump, temperature adjusting means comprising a heating means or both a heating means and a cooling means, and tubing for fluidly connecting said conduits, fluid pump, and temperature adjusting means, respectively, wherein the fluid pump is capable of pumping a heating fluid heated by the heating means through the conduits for heating the vacuum chamber, or of pumping both a heating fluid heated by the heating means and a cooling fluid cooled by the cooling means through the conduits for both heating and cooling the vacuum chamber, respectively.

32. Temperature control system according to claim 31,
wherein the temperature adjusting means comprises both the heating means and the cooling means, whereby the heating means and the cooling means are integrated in a combined temperature adjusting device.

33. Temperature control system according to claim 31,
wherein the cooling fluid and the heating fluid are different fluids.

34. Temperature control system according to claim 31,
wherein a common temperature adjusting fluid is used as both the cooling fluid and the heating fluid, respectively.

35. Temperature control system according to claim 31,
wherein the heating means is capable of heating the heating fluid to a temperature of 100° C. or higher.

36. Temperature control system according to claim 31,
wherein the cooling means is capable of cooling the cooling fluid to a temperature of 0° C. or lower.

37. Temperature control system according to claim 31,
wherein the temperature control system comprises one or more sensors for measuring the temperature of the vacuum chamber and/or for measuring the temperature of the heating fluid and/or the cooling fluid, respectively.

38. Temperature control system according to claim 31,
wherein the tubing is provided as detachable tubing for allowing a separation of the fluid pump, and the temperature adjusting means, respectively, from the conduits.

39. Vacuum system with a vacuum chamber, the vacuum chamber comprising a chamber wall enclosing a vacuum volume, a vacuum pump system connected to the vacuum chamber for evacuating the vacuum volume, and a temperature control system for adjusting a temperature of a vacuum chamber,
wherein the temperature control system is constructed according to claim 31, and the conduits of the temperature control system are thermally coupled to the chamber wall.

40. Vacuum system according to claim 39,
wherein the conduits are at least partly integrated into the chamber wall.

41. Vacuum system according to claim 40,
wherein the chamber wall is at least partly constructed as a double-walled structure, whereby an interstitial space of the double-walled structure forms at least part of the conduits.

42. Vacuum system according to claim 40,
wherein the chamber wall comprises one or more internal ducts in the bulk of the chamber wall, wherein the one or more internal ducts form at least part of the conduits.

43. Vacuum system according to claim 42,
wherein the one or more internal ducts are provided as pairs of straight and V-shaped arranged bores.

44. Vacuum system according to claim 39,
wherein the conduits are at least partly attached to the outside of the chamber wall.

45. Vacuum system according claim 44,
wherein the conduits are at least partly provided as tubes, wherein the tubes are attached and thermally coupled to the outside of the chamber wall.

46. Vacuum system according claim 45,
wherein the tubes are soldered and/or welded to the outside of the chamber wall.

47. Vacuum system according claim 45,
wherein the tubes consists of a material with a thermal conductivity higher than 200 W/mK.

48. Vacuum system according to claim 44,
wherein elongated concave structural elements are attached to the chamber wall, whereby an interstitial space between the chamber wall and the respective structural element forms at least part of the conduits.

49. Vacuum system according to claim 48,
wherein the structural elements are soldered and/or welded to the outside of the chamber wall.

50. Vacuum system according to claim 39,
wherein conduits are arranged such at the chamber wall that the temperature control system is capable of cooling and heating, respectively, of more than 25% of the chamber wall.

51. Vacuum system according to claim 39,
wherein conduits are at least essentially evenly or evenly distributed over the chamber wall.

52. Vacuum system according to claim 39,
wherein the vacuum system comprises one or more sensors for measuring the temperature of the vacuum chamber and/or for measuring the temperature of the heating fluid and/or the cooling fluid, respectively.

53. Method of adjusting the temperature of a vacuum chamber of a vacuum system according to claim 39, comprising the steps of
a) measuring the temperature of the vacuum chamber;
b) evaluating the temperature measured in step a) at least by comparing the temperature with an upper limit value and/or a lower limit value; and
c) cooling or heating, respectively, of the vacuum chamber by the temperature control system, if the temperature evaluated in step b) exceeds the upper limit value or falls short of the lower limit value.

54. Method according to claim 53,
wherein in step a) the temperature of the vacuum chamber is measured directly and/or
wherein in step a) the temperature of the vacuum chamber is measured indirectly by measuring the temperature of the heating fluid and/or the cooling fluid, respectively.

55. Method according to claim 53,
wherein in step b) the measured temperature is compared with both the upper limit value and the lower limit value.

56. Method according to claim 55,
wherein the upper limit value is higher than the lower limit value.

57. Method according to claim 55,
wherein the lower limit value is higher than the upper limit value.

58. Method according to claim 53,
wherein steps a) to c) are repeatedly carried out for a closed loop control of the temperature of the vacuum chamber.

59. Method according to claim 53,
wherein a heating of the vacuum chamber by the temperature control system can be used for a bake out procedure of the vacuum chamber.

60. Method according to claim 53,
wherein the temperature control system comprises a detachable tubing, and
wherein before the first execution of step a) the detachable tubing is used connect the fluid pump,
the temperature adjusting means, and the conduits,
and/or wherein after the last completion of step c) the detachable tubing is used separate the fluid pump, the temperature adjusting means, and the conduits.
